(19) United States
(12) Patent Application Publication
(10) Pub. No.: US 2014/0327051 A1
(43) Pub. Date: Nov. 6, 2014

(54) IMAGE SENSOR AND METHOD OF MANUFACTURING THE SAME

(71) Applicant: Samsung Electronics Co., Ltd., Suwon-si (KR)

(72) Inventors: Jung-chak AHN, Yongin-si (KR); Yi-tae KIM, Hwaseong-si (KR); Eun-sub SHIM, Anyang-si (KR); Kyung-ho LEE, Suwon-si (KR)

(73) Assignee: Samsung Electronics Co., Ltd., Suwon-si (KR)

(21) Appl. No.: 14/168,657

(22) Filed: Jan. 30, 2014

(30) Foreign Application Priority Data
May 2, 2013 (KR) 10-2013-0049614

(51) Int. Cl. H01L 27/148; H01L 31/18

(52) U.S. Cl. CPC H01L 27/14806; H01L 31/18
USPC 257/228; 438/69

(57) ABSTRACT

An image sensor and a method of manufacturing the image sensor are provided. The image sensor may include a photo detecting device and a charge storage device. The image sensor may further include a trench and a shield which blocks light from being absorbed by the charge storage device. The charge storage device may temporarily store accumulated charges by the photo detecting device.

### CROSS-REFERENCE TO RELATED APPLICATIONS

This application claims priority from Korean Patent Application No. 10-2013-0049614, filed on May 2, 2013, in the Korean Intellectual Property Office, the entire disclosure of which is hereby incorporated by reference.

### BACKGROUND

Exemplary embodiments relate to an image sensor and a method of manufacturing the same. In particular, exemplary embodiments relate to an image sensor, which supports a global shutter method, and a method of manufacturing the same.

An image sensor of the related art captures an image and converts the captured image to an electric signal. An image sensor of the related art is used in a camera mounted on a vehicle, a security system, and a robot. Further, the image sensor of the related art may also be used as a camera mounted on an electronic device for general consumers, e.g., a digital camera, a camera for a mobile phone, and a portable camcorder. An image sensor of the related art may be provided with a pixel array including unit pixels. Each unit pixel may include a photo detecting device. A photo detecting device may generate an electric signal according to the intensity of absorbed light. A photodiode is a type of photo detecting device that may absorb light and generate current corresponding to the intensity of the absorbed light.

In the related art, an image sensor may be produced through a semiconductor manufacturing process. An image sensor may include photo detecting devices, transistors configured to control the photo detecting devices, and circuits configured to drive a pixel array. The photo detecting devices, the transistors, and the circuits may be formed through a semiconductor manufacturing process. A backside illuminated image sensor may also be formed, in which a transistor and a wiring layer are formed on one surface of a semiconductor layer in which a photo detecting device. Further, light is incident on the other surface of the semiconductor layer.

### SUMMARY

Exemplary embodiments may provide an image sensor, which supports a global shutter method by blocking a part of incident light, and a method of manufacturing the same.

According to an aspect of the exemplary embodiments, there is provided an image sensor including: a semiconductor layer which includes a first surface and a second surface which is opposite to the first surface; a photo detecting device which forms part of the first surface of the semiconductor layer and is disposed within the semiconductor layer to accumulate charges according to light absorbed from the second surface of the semiconductor layer; a charge storage device which forms part of the first surface of the semiconductor layer and is disposed within the semiconductor layer to temporarily store the accumulated charges by the photo detecting device; a first transfer transistor which transfers the accumulated charges by the photo detecting device to the charge storage device, the first transfer transistor includes a gate disposed on the first surface of the semiconductor layer; and a trench disposed from the second surface of the semiconductor layer toward a region between portions where the photo detecting device and the charge storage device form part of the first surface of the semiconductor layer.

The image sensor may further include: a material layer disposed on the second surface of the semiconductor layer; and a shield disposed within the material layer to block light from being absorbed by the charge storage device through the second surface of the semiconductor layer.

The shield may include a metal.

The trench may be filled with a material having a lower refractive index than a refractive index of a material forming the semiconductor layer.

The semiconductor layer may be formed of epitaxially grown silicon, and the trench may be filled with an oxide, a nitride, or air.

The trench may be disposed from the second surface of the semiconductor layer toward a region surrounding a portion where the charge storage device forms part of the first surface of the semiconductor layer.

The image sensor may further include: a floating diffusion in which the stored charges in the charge storage device are transferred; and a second transfer transistor which transfers the stored charges in the charge storage device to the floating diffusion, the second transfer transistor includes a gate disposed on the first surface of the semiconductor layer, wherein the trench is disposed from the second surface of the semiconductor layer toward the first surface of the semiconductor layer, and disposed between a region where the photo detecting device and the floating diffusion form part of the first surface of the semiconductor layer.

The image sensor may further include: at least one unit pixel which includes the photo detecting device and the charge storage device; and a pixel isolation barrier disposed between adjacent unit pixels of the at least one unit pixel.

The pixel isolation barrier may be filled with a material having a lower refractive index than a refractive index of a material forming the semiconductor layer.

According to another aspect of the exemplary embodiments, there is provided a method of manufacturing an image sensor, the method including: forming a photo detecting device and a charge storage device, either simultaneously or separately, by implanting impurities into a first surface of a semiconductor layer; forming a gate of a transfer transistor on the first surface of the semiconductor layer, the transfer transistor transferring charges between the photo detecting device and the charge storage device; and forming a trench from a second surface of the semiconductor layer, which is opposite to the first surface, to a region where the photo detecting device and the charge storage device form part of the first surface of the semiconductor layer.

The method may further include: forming a material layer on the second surface of the semiconductor layer; and forming a shield within the material layer, the shield blocking light from being absorbed by the charge storage device through the second surface of the semiconductor layer.

The method may further include: forming a color filter layer on a surface of the material layer which is opposite to a surface contacting the second surface of the semiconductor layer; and forming a lens layer on one surface of the color filter layer which is opposite to a surface form the material layer.

The trench may be filled with a material having a lower refractive index than a refractive index of a material forming the semiconductor layer.

The trench may be disposed from the second surface of the semiconductor layer toward a region surrounding a portion where the charge storage device forms part of the first surface of the semiconductor layer.

The method may further include forming a pixel isolation barrier between adjacent unit pixels of at least one unit pixel which includes a pair of the photo detecting device and the charge storage device.

According to yet another aspect of the exemplary embodiments, there is provided a unit pixel of an image sensor including: a semiconductor layer including a first surface and a second surface opposite to the first surface; a transistor layer disposed on the first surface of the semiconductor layer; a color filter layer stacked on the second surface of the semiconductor layer; a lens layer stacked on the color filter layer; a photo detecting device which forms part of the first surface of the semiconductor layer; and a charge storing device which forms part of the first surface of the semiconductor layer. The lens layer focuses incident light on a photo detecting device and the color filter layer transmits incident light through the lens layer so that only light of a specific wavelength is incident on the photo detecting device.

### BRIEF DESCRIPTION OF THE DRAWINGS

Exemplary embodiments will be more clearly understood from the following detailed description taken in conjunction with the accompanying drawings in which:

FIGS. 1A and 1B are diagrams illustrating a unit pixel of an image sensor, according to an exemplary embodiment;

FIG. 2 is a circuit diagram illustrating the unit pixel having the structure of FIGS. 1A and 1B, according to an exemplary embodiment;

FIG. 3 is a schematic diagram of an image sensor including the unit pixel of FIG. 2, according to an exemplary embodiment;

FIG. 4 is a cross-sectional view illustrating a unit pixel of an image sensor, according to an exemplary embodiment;

FIGS. 5A and 5B are diagrams illustrating a unit pixel of an image sensor, according to an exemplary embodiment;

FIGS. 6 and 7 are diagrams illustrating a unit pixel of an image sensor according to exemplary embodiments;

FIGS. 8A to 8E are schematic diagrams illustrating a method of manufacturing an image sensor including the unit pixel of FIG. 4, according to an exemplary embodiment;

FIGS. 9A and 9B are schematic diagrams illustrating some operations of a method of manufacturing an image sensor including the unit pixel of FIG. 4, according to an exemplary embodiment;

FIG. 10 is a block diagram illustrating a configuration of an image sensor according to an exemplary embodiment;

FIG. 11 is a block diagram of a system including the image sensor of FIG. 10, according to an exemplary embodiment; and

FIG. 12 is a block diagram illustrating an electronic system including an image sensor and an interface, according to an exemplary embodiment.

### DETAILED DESCRIPTION OF EXEMPLARY EMBODIMENTS

The exemplary embodiments are merely described below to explain aspects, by referring to the figures, to explain aspects of the inventive concept.

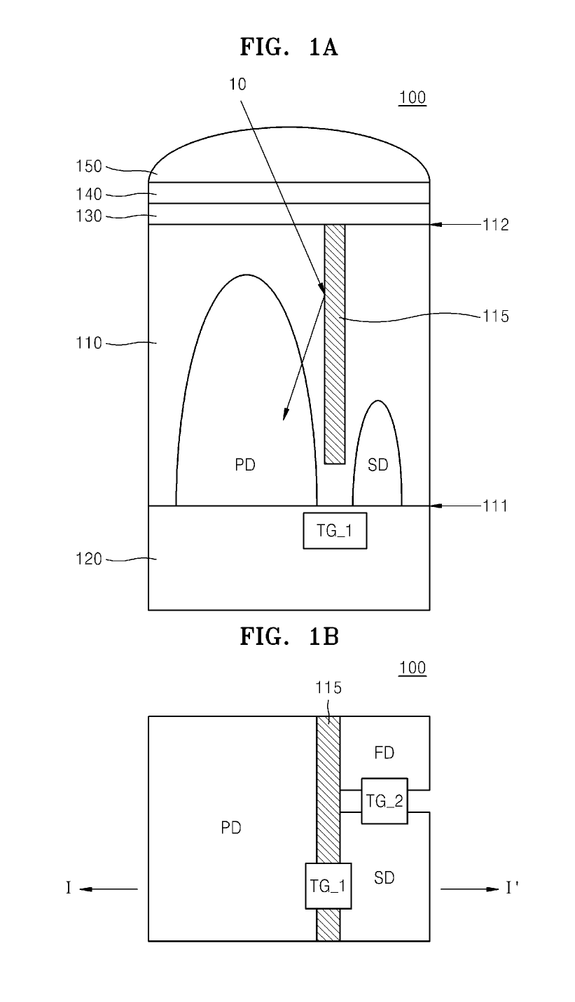

FIGS. 1A and 1B are diagrams illustrating a unit pixel 100 of an image sensor according to an embodiment. FIG. 1A is a cross-sectional view of the unit pixel 100, taken along line I-I′ of FIG. 1B, and FIG. 1B is a view of the bottom of the unit pixel 100 of FIG. 1A.

As illustrated in FIG. 1A, the unit pixel 100 may include a semiconductor layer 110, a transistor layer 120, a color filter layer 140, and a lens layer 150. The semiconductor layer 110 may include a first surface 111 and a second surface 112 that are opposite to each other, and the transistor layer 120 may be formed on the first surface 111 of the semiconductor layer 110. Although not illustrated in FIG. 1A, a wiring layer may be further formed on one surface of the transistor layer 120 which is opposite to the first surface 111 of the semiconductor layer 110. The wiring layer includes a plurality of wires which are each formed of a conductive material. Each of the semiconductor layer 110 and the transistor layer 120 may be one of a bulk substrate, an epitaxial substrate, and a silicon on insulator (SOI) substrate.

The color filter layer 140 and the lens layer 150 may be sequentially stacked in this order on the second surface 112 of the semiconductor layer 110. The lens layer 150 may focus incident light on a photo detecting device PD. The color filter layer 140 may transmit light incident through the lens layer 150 so that only light of a necessary wavelength is incident on the photo detecting device PD. The unit pixel 100 may further include an material layer 130 disposed between the semiconductor layer 110 and the color filter layer 140. The material layer 130 may be a passivation layer for protecting the semiconductor layer 110, and may function to prevent scattering or reflection of light.

The semiconductor layer 110 may include the photo detecting device PD, a charge storage device SD, and a trench 115. The photo detecting device PD and the charge storage device SD may form part of the first surface 111 of the semiconductor layer 110. According to the exemplary embodiment, the photo detecting device PD may be a photodiode and may generate current by absorbing light incident through the lens layer 150, the color filter layer 140, and the material layer 130. While the photo detecting device PD is absorbing light, when a charge transfer path between the photo detecting device PD and the outside is blocked, charges due to the current generated by the photo detecting device PD may accumulate in the photo detecting device PD. An amount of charges accumulated in the photo detecting device PD increases with the intensity of light absorbed by the photo detecting device PD. Therefore, the intensity of the absorbed light may be detected from the amount of charges accumulated in the photo detecting device PD.

The charge storage device SD functions to temporarily store the charges generated according to the light absorption of the photo detecting device PD. The image sensor may include a pixel array including a plurality of unit pixels 100 that may control the pixel array using a global shutter method. In order to support the global shutter method, the unit pixel 100 may include a charge storage device which temporarily stores the charges accumulated in the photo detecting device PD. For example, as illustrated in FIG. 1A, the unit pixel 100 may include the charge storage device SD The global shutter method is described below.

According to the exemplary example, the trench 115 may be formed by a trench isolation method. The trench isolation method may be classified into shallow trench isolation (STI) and deep trench isolation (DTI), depending on the depth of the trench. Compared with a local oxidation of silicon (LOCOS), an isolation barrier having the SDI and DTI structures does not cause a bird's beak. Hence, an active region of a substrate may be preserved without erosion. The trench 115 may be a DTI formed from the second surface 112 toward the first surface 111 of the semiconductor layer 110.

According to the exemplary embodiment, the trench 115 may be formed from the second surface 112 of the semiconductor layer 110 toward a region between portions where each of the photo detecting device PD and the charge storage device SD form part of the first surface 111 of the semiconductor layer 110. The trench 115 may include a material having a lower refractive index than that of the semiconductor layer 110. For example, when a material of the semiconductor layer 110 is silicon (Si), the trench 115 may include materials having a lower refractive index than that of silicon, e.g., oxide, nitride, or air.

Light incident on the charge storage device SD may influence an amount of charge stored by the charge storage device SD. For example, when the charge storage device SD is a diode, the charge storage device SD may accumulate charges according to absorbed light, similar to the photodiode. Therefore, there may be an error in the amount of charges that are temporarily stored in the charge storage device SD and then transferred to the outside of the unit pixel 100.

According to the exemplary embodiment, the trench 115 may shield a part of light incident on the charge storage device SD. As illustrated in FIG. 1A, light 10 may be incident on the semiconductor layer 110 through the lens layer 150 and the color filter layer 140. The light 10 incident on the semiconductor layer 110 may be reflected from a contact surface between the semiconductor layer 110 and the trench 115, so that the light 10 is not incident on the charge storage device SD. For example, when a refractive index of the material included in the trench 115 is lower than a refractive index of the material of the semiconductor layer 110, and an incidence angle of light incident on the trench 115 is larger than a critical angle, the light 10 may be reflected from the surface between the semiconductor layer 110 and the trench 115 due to total reflection.

The transistor layer 120 may include transistors capable of controlling the photo detecting device PD, the charge storage device SD, etc. For example, as illustrated in FIG. 1A, the unit pixel 100 may include a first transfer transistor that forms a charge transfer path between the photo detecting device PD and the charge storage device SD, and a gate TG_1 of the first transfer transistor may be formed within the transistor layer 120.

FIG. 1B is diagram of the transistor layer 120 on the bottom of the unit pixel 100 of FIG. 1A. As illustrated in FIG. 1B, the charge transfer between the photo detecting device PD and the charge storage device SD may be controlled by the gate TG_1 of the first transfer transistor. In addition, a floating diffusion FD may be formed within the semiconductor layer 110, and the floating diffusion FD may receive charges stored by the charge storage device SD. A voltage according to the charges received by the floating diffusion FD may be amplified by transistors (not illustrated) formed in the transistor layer 120, and be output to the outside of the unit pixel 100.

As illustrated in FIG. 1B, a second transfer transistor may form a charge transfer path between the charge storage device SD and the floating diffusion FD, and a gate TG_2 of the second transfer transistor may be formed on the first surface 111 of the semiconductor layer 110. As illustrated in FIG. 1B, the trench 115 may be formed between the photo detecting device PD and the charge storage device SD so as to block light incident on the charge storage device SD.

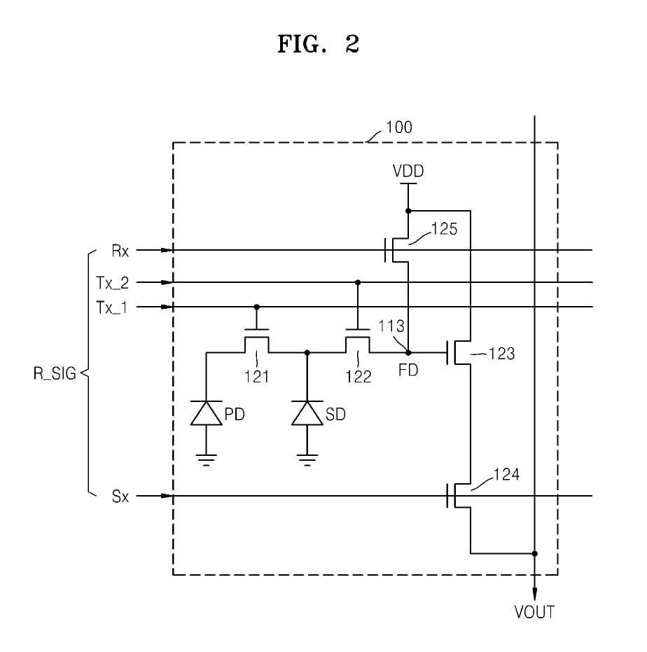

FIG. 2 is a circuit diagram illustrating the unit pixel 100 having the structure of FIGS. 1A and 1B, according to an exemplary embodiment. The unit pixel 100 may receive a row signal R_SIG from the outside and output an output voltage VOUT to the outside. The row signal R_SIG may be applied to gates of transistors included in the unit pixel 100 so as to control the transistors included in the unit pixel 100, and may include a reset signal Rx, first and second transfer signals Tx_1 and Tx_2, and a select signal Sx. The output voltage VOUT may be determined according to the intensity of light detected by the unit pixel 100.

The unit pixel 100 may include a photo detecting device PD, a charge storage device SD, a first transfer transistor 121, a second transfer transistor 122, a source-follower transistor 123, a select transistor 124, and a reset transistor 125. In addition, the unit pixel 100 may include a floating diffusion FD which is a node where the second transfer transistor 122, the source-follower transistor 123, and the reset transistor 125 are electrically connected to one another.

The photo detecting device PD absorbs light and converts the absorbed light into an electric signal. Examples of the photo detecting device PD may include a photodiode, a photogate, and a phototransistor. The charge storage device SD may temporarily store charges accumulated in the photo detecting device PD. Examples of the charge storage device SD may be a capacitor and a diode. An example in which the photo detecting device PD is a photodiode and the charge storage device SD is a diode is illustrated in FIG. 2, though the exemplary embodiments are not limited thereto.

The first transfer transistor 121 may transmit or block the charges accumulated in the photo detecting device PD to or from the charge storage device SD according to the first transfer signal Tx_1. For example, while the photo detecting device PD absorbs light and accumulate charges, the first transfer signal Tx_1 having a voltage capable of turning off the first transfer transistor 121 may be applied to the gate of the first transfer transistor 121. The second transfer transistor 122 may transmit or block the charges stored in the charge storage device SD to or from the floating diffusion FD according to the second transfer signal Tx_2. For example, in order to output the charges stored in the charge storage device SD through the floating diffusion FD to the outside of the unit pixel 100, the second transfer signal Tx_2 having a voltage capable of turning on the second transfer transistor 122 may be applied to the gate of the second transfer transistor 122.

The source-follower transistor 123 may amplify the voltage of the floating diffusion FD, and the select transistor 124 may selectively output the amplified voltage according to the select signal Sx. The reset transistor 125 may connect the floating diffusion FD to a power supply voltage VDD source or disconnect the floating diffusion FD from the power supply voltage VDD source according to the reset signal Rx, so that the voltage of the floating diffusion FD becomes the reset voltage that is approximately the power supply voltage VDD. The unit pixel 100, including the component that amplifies the electric signal generated by converting the light absorbed by the photo detecting device PD, may also be referred to as an active pixel sensor (APS). It is obvious that the exemplary embodiment may be the unit pixel 100 of FIG. 2 and other APS, including a photo detecting device PD and a charge storage device SD.

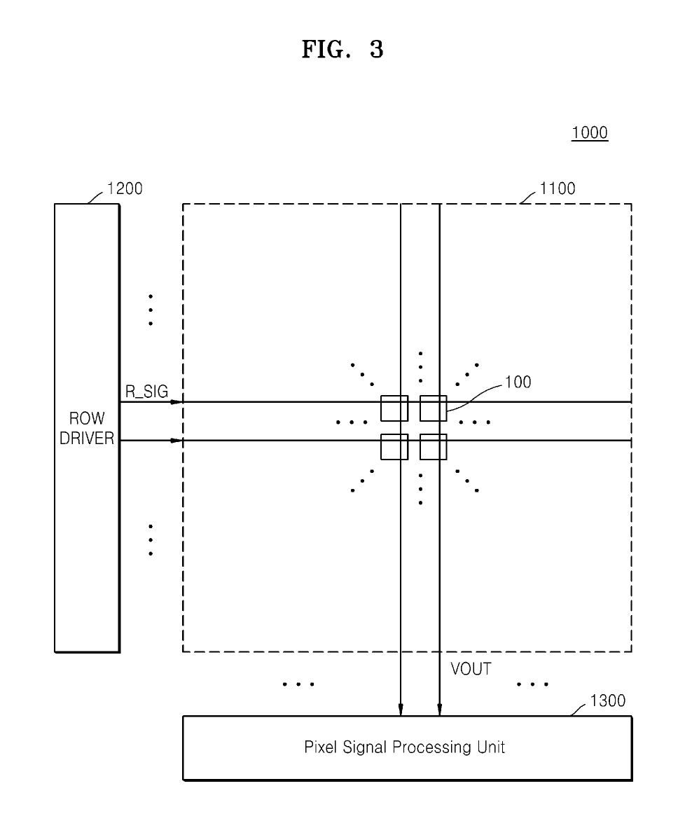

FIG. 3 is a schematic diagram of an image sensor 1000 including the unit pixel 100 of FIG. 2, according to an exemplary embodiment. The image sensor 1000 may include a pixel array 1100, a row driver 1200, a pixel signal processing unit 1300. The pixel array 1100 may include a plurality of unit pixels 100 which are uniformly arranged in a horizontal direction. The row driver 1200 may output the row signal R_SIG to the pixel array 1100. As described above with reference to FIG. 2, the row signal R_SIG may include a plurality of signals which may control each of the unit pixels 100 included in the pixel array 1100.

The pixel signal processing unit 1300 may receive the output voltage VOUT output from at least one unit pixel 100 included in the pixel array 1100, and measure the magnitude of the output voltage VOUT. The plurality of unit pixels 100 constituting a row may share the same row signal R_SIG, and the plurality of unit pixels 100 constituting a column may share a signal line from which the output voltages VOUT thereof are output. Since the pixel array 1100 includes more than tens of thousands of unit pixels 100, the pixel signal processing unit 1300 may not simultaneously measure the output voltages VOUT of all the unit pixels 100 included in the pixel array 110. Therefore, after measuring the output voltages VOUT output from some of the unit pixels 100 included in the pixel array 1100, the pixel signal processing unit 1300 may measure the output voltages VOUT output from other unit pixels 100. For example, the pixel signal processing unit 1300 may simultaneously measure the output voltages VOUT output from the unit pixels 100 constituting a single row included in the pixel array 1100.

Considering these characteristics of the pixel signal processing unit 1300, a rolling shutter method, which may be implemented through the control of the row driver 1200, starts periods of exposure to light at different time points and ends periods of exposure to light at different time points with respect to the unit pixels 100 constituting different rows. The periods during which the unit pixels 100 included in the pixel array 1100 are exposed to light must have the same duration. Thus, using a time difference between the ends of periods during which the unit pixels 100 constituting different rows are exposed to light, the output voltages VOUT output from the unit pixels 100 constituting the row are measured immediately after the end of the period during which the unit pixels 100 constituting each row are exposed to light. In the rolling shutter method, the plurality of unit pixels 100 included in the pixel array 1100 are exposed to light at different time points. Therefore, in detecting a moving image, the rolling shutter may cause image distortion.

On the other hand, the global shutter method, which may be implemented through the control of the row driver 1200, matches the start and the end of the periods during which the unit pixels 100 included in the pixel array 1100 are exposed to light, and measures the output voltages VOUT output from the respective unit pixels 100 at different time points. Unlike the rolling shutter, the global shutter may remove image distortion of even a moving image because all unit pixels 100 included in the pixel array 1100 are exposed to light at the same time points. Therefore, after the end of the period during which each of the unit pixels 100 is exposed to light, each of the unit pixels 100 may store charges accumulated in the photo detecting device included in the unit pixels 100, until the output voltage VOUT output from each of the unit pixels 100 is measured by the pixel signal processing unit 1300. In the exemplary embodiments illustrated in FIGS. 1A, 1B, and 2, the charge storage device SD may temporarily store charges accumulated in the photo detecting device PD, until the output voltage VOUT according to charges accumulated in the photo detecting device PD is measured by the pixel signal processing unit 1300.

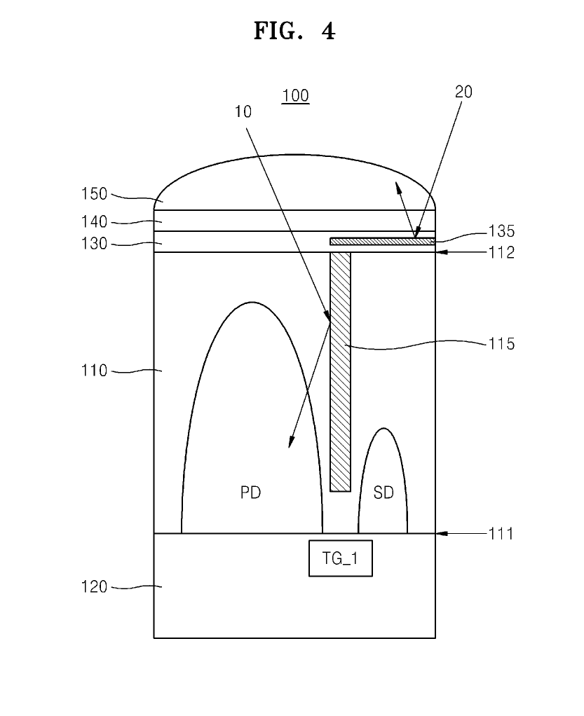

FIG. 4 is a cross-sectional view illustrating a unit pixel 100 of an image sensor, according to an exemplary embodiment. As illustrated in FIG. 4, the unit pixel 100 may include a semiconductor layer 110, a transistor layer 120, a material layer 130, a color filter layer 140, and a lens layer 150. The semiconductor layer 110 may include a first surface 111 and a second surface 112 which are opposite to each other, and the transistor layer 120 may be formed on the first surface 111 of the semiconductor layer 110. In addition, the material layer 130, the color filter layer 140, and the lens layer 150 may be sequentially stacked in this order on the second surface 112 of the semiconductor layer 110. Since the description of the semiconductor layer 110, the transistor layer 120, the color filter layer 140, and the lens layer 150 are substantially identical to that described above with reference to FIG. 1A, a detailed description thereof is omitted herein.

According to the exemplary embodiment, the unit pixel 100 may include the material layer 130 between the semiconductor layer 110 and the color filter layer 140. The material layer 130 may be an insulation layer, and may be a passivation layer for protecting the semiconductor layer 110. In addition, the material layer 130 may prevent scattering or reflection of light. In this case, the material layer 130 may be provided as a multi-layer film in which materials having different refractive indexes are stacked. For example, the material layer 130 may include a stacked film in which an oxide film and a nitride film are stacked (oxide film/nitride film or nitride film/oxide film) or a stacked film in which an oxide film and a carbon-containing film (SiC) are stacked (oxide film/SiC or SiC/oxide film). In particular, the oxide film may be formed as one selected from a BoroPhosphoSilicate Glass (BPSG) film, a PhosphoSilicate Glass (PSG) film, a BoroSilicate Glass (BSG) film, an Undoped Silicate Glass (USG) film, a Tetra Ethyl Ortho Silicate (TEOS) film, or a High Density Plasma (HDP) film. The nitride film may be formed as a silicon nitride film (SixNy, where x and y are natural numbers) or a silicon oxynitride film (SixOyNz, where x, y, and z are natural numbers).

According to the exemplary embodiment, the material layer 130 may include a shield 135. The shield 135 may be formed in the material layer 130 so that light incident on the material layer 130, after passing through the lens layer 150 and the color filter layer 140, is prevented from being absorbed by the charge storage device SD. For example, as illustrated in FIG. 4, the shield 135 may be disposed opposite to the charge storage device SD at a position in the material layer 130. In addition, the shield 135 may extend to a position of the material layer 130 that is opposite to the trench 115. Accordingly, a part 10 of the light incident on the material layer 130, after passing through the lens layer 150 and the color filter layer 140, may pass through the material layer 130 and be incident on the semiconductor layer 110. Further, the part 10 of the incident light may not be incident on the charge storage device SD due to total reflection on the trench 115. Another part 20 of the light incident on the material layer 130 after passing through the lens layer 150 and the color filter layer 140 may be blocked by the shield 135 included in the material layer 130. Thus, the part 20 of the incident light may not be incident on the semiconductor layer 110. Therefore, the charge storage device SD may store charges accumulated in the photo detecting device PD, without influence of light. The shield 135 may include a material that does not transmit light, e.g., a metal.

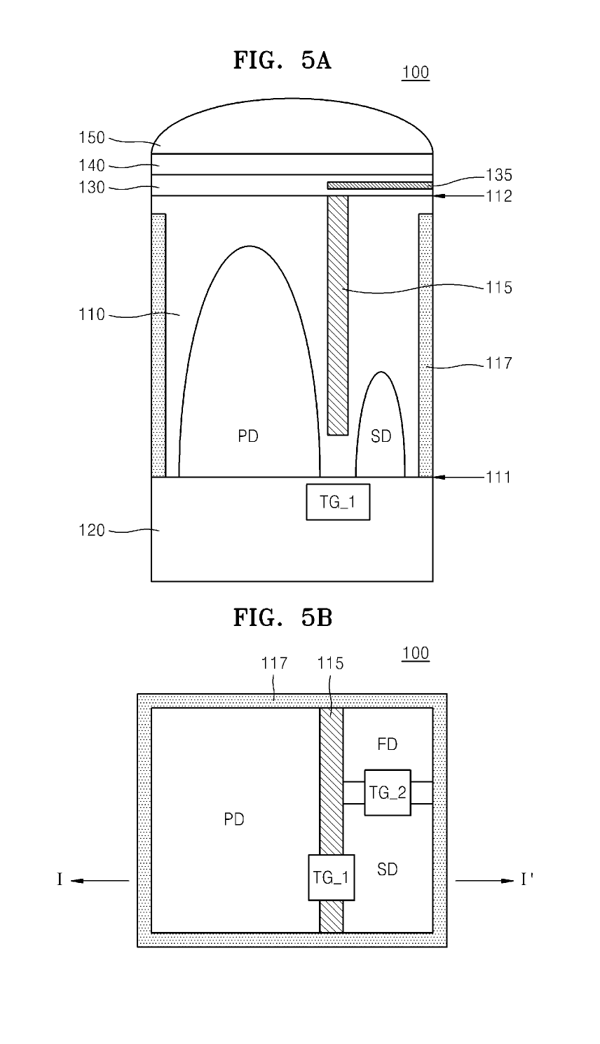

FIGS. 5A and 5B are diagrams illustrating a unit pixel 100 of an image sensor, according to an exemplary embodiment. FIG. 5A is a cross-sectional view of the unit pixel 100, taken along line I-I′ of FIG. 5B, and FIG. 5B is a view of the bottom of the unit pixel 100 of FIG. 5A.

As illustrated in FIG. 5A, the unit pixel 100 may include a semiconductor layer 110, a transistor layer 120, a material layer 130, a color filter layer 140, and a lens layer 150. The semiconductor layer 110 may include a first surface 111 and a second surface 112 which are opposite to each other, and the transistor layer 120 may be formed on the first surface 111 of the semiconductor layer 110. In addition, the material layer 130, the color filter layer 140, and the lens layer 150 may be sequentially stacked in this order on the second surface 112 of the semiconductor layer 110. Since the description of the semiconductor layer 110, the transistor layer 120, the material layer 130, the color filter layer 140, and the lens layer 150 is substantially identical to that described above with reference to FIGS. 1A and 4, a detailed description thereof is omitted herein.

According to the exemplary embodiment, the semiconductor layer 110 may include a pixel isolation barrier 117. The pixel isolation barrier 117 may be vertically disposed in the semiconductor layer 110 to form a boundary between adjacent pixels. The pixel isolation barrier 117 may be a DTI formed from the first surface 111 toward the second surface 112 of the semiconductor layer 110, or may be a DTI formed from the second surface toward the first surface 111 of the semiconductor layer 110. In FIG. 5A, the pixel isolation barrier 117 is illustrated as a trench formed from the first surface 111 toward the second surface 112 of the semiconductor layer 110, but the pixel isolation barrier 117 is not limited thereto. For example, the pixel isolation barrier 117 may be provided as a trench formed from the second surface 112 toward the first surface 111 of the semiconductor layer 110. In addition, the pixel isolation barrier 117 may be separate from the second surface 112 of the semiconductor layer 110, as illustrated in FIG. 5A, or may be part of the second surface 112 of the semiconductor layer 110.

FIG. 5B is diagram of the transistor layer 120 on the bottom of the unit pixel 100 of FIG. 5A. As illustrated in FIG. 5B, the pixel isolation barrier 117 may be formed to isolate unit pixels 100 each including a pair of the photo detecting device PD and the charge storage device SD. In addition, the trench 115 may be formed between the photo detecting device PD and the charge storage device SD.

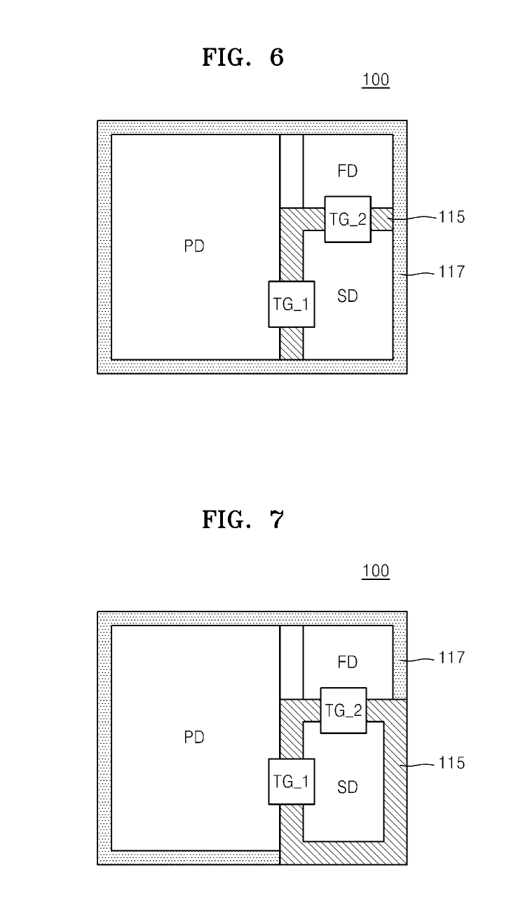

FIGS. 6 and 7 are diagrams illustrating a unit pixel 100 of an image sensor, according to exemplary embodiments. The unit pixel 100 may include a pixel isolation barrier 117 which may be formed on sides of a photo detecting device PD, a charge storage device SD, and a floating diffusion FD.

According to the exemplary embodiment, the pixel isolation barrier 117 may be formed to isolate unit pixels 100 from each other, as illustrated in FIG. 6, or a trench 115 may be formed between the photo detecting device PD and the charge storage device SD. In addition, in this exemplary embodiment, the trench 115 may be formed between the charge storage device SD and the floating diffusion FD.

According to the exemplary embodiment, as illustrated in FIG. 7, the trench 115 may be formed from the second surface 112 of FIG. 5A toward the region that surrounds the portion where the photo detecting device SD forms part of the first surface 111 of FIG. 5A. Accordingly, it is possible to totally reflect light incident on the charge storage device SD from an arbitrary side of the charge storage device SD.

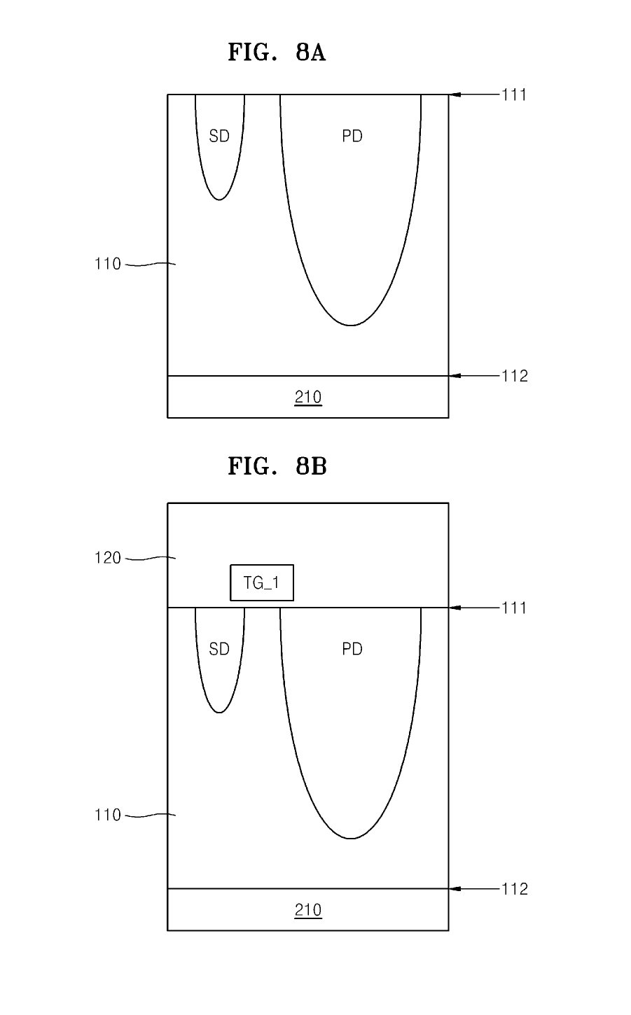

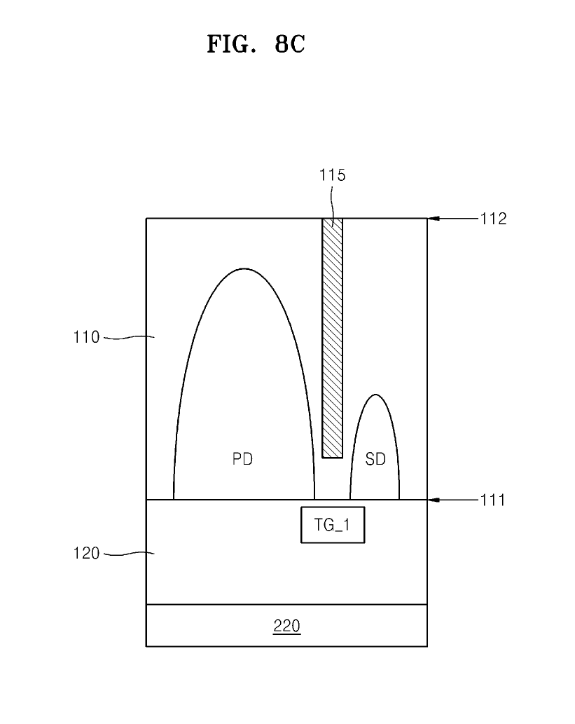

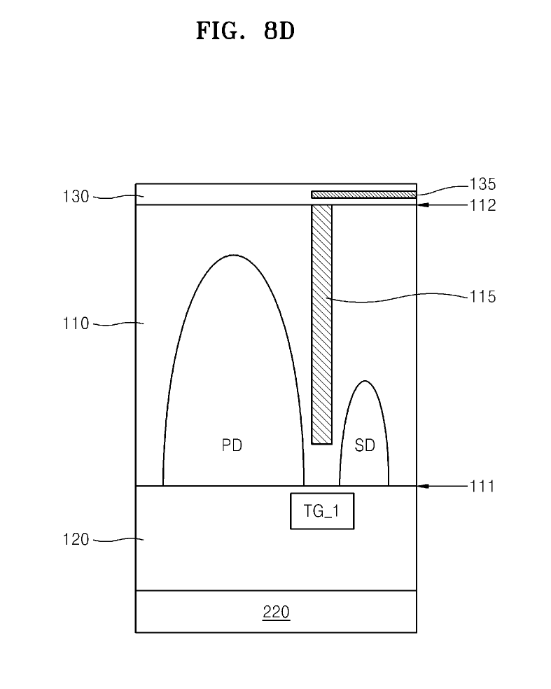

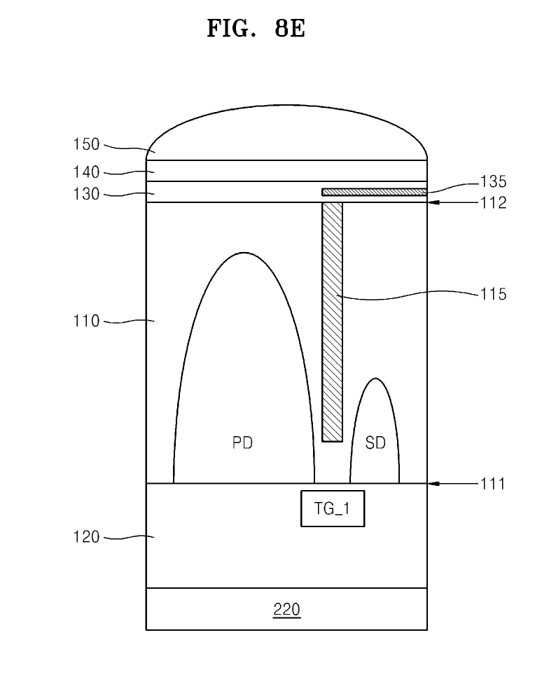

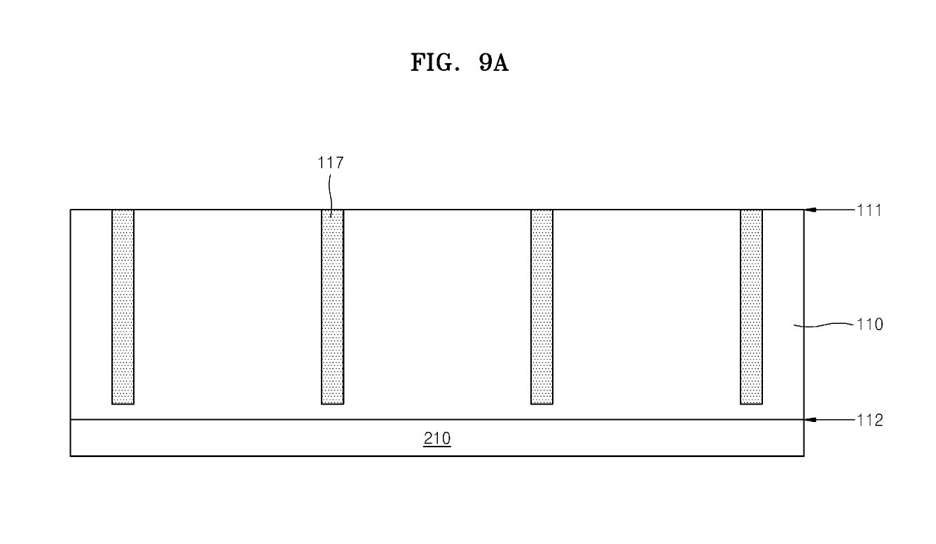

FIGS. 8A to 8E are schematic diagrams illustrating a method of manufacturing an image sensor including the unit pixel 100 of FIG. 4 according to an exemplary embodiment. As illustrated in FIG. 4, the unit pixel 100 may include a semiconductor layer 110, a transistor layer 120, a material layer 130, a color filter layer 140, and a lens layer 150. According to the exemplary embodiment, the semiconductor layer 110, the transistor layer 120, the material layer 130, the color filter layer 140, and the lens layer 150 may be formed in the unit pixel 100 in this order.

According to the exemplary embodiment, referring to FIG. 8A, the semiconductor layer 110 may be formed on a first support substrate 210. The semiconductor layer 110 may be one of a bulk substrate, an epitaxial substrate, and an SOI substrate. A surface where the first support substrate 210 and the semiconductor layer 110 contact each other is referred to as a second surface 112 of the semiconductor layer 110, and a surface of the semiconductor layer 110 opposite to the second surface 112 is referred to as a first surface 111 of the semiconductor layer 110. The photo detecting device PD and the charge storage device SD may be formed by implanting impurities into the first surface 111 of the semiconductor layer 110.

Referring to FIG. 8B, the transistor layer 120 may be formed on the first surface 111 of the semiconductor layer 110. The transistor layer 120 may include a gate TG_1 of a first transfer transistor formed on the first surface 111 of the semiconductor layer 110, and the first transfer transistor may transfer charges between the photo detecting device PD and the charge storage device SD. Although only the gate TG_1 of the first transfer transistor is illustrated in FIG. 8B, the gate TG_2 of the second transfer transistor of FIG. 1B and the transistor layers 120 of the active elements for transferring or processing an electric signal according to charges accumulated in the photo detecting device PD may also be formed within the transistor layer 120. Although not illustrated in FIG. 8B, a wiring layer (not illustrated) may be formed on the transistor layer 120. The wiring layer may have a structure in which a wire and an intermediate insulation film are stacked, or may be formed through deposition and etching processes. The wire may be formed of a conductive material, e.g., a metal or an alloy film including a mixture of at least two kinds of metal. The intermediate insulation film may be formed of an insulation material, e.g., silicon oxide. A multi-layer wire may be formed by repeating the formation of the wire and the formation of the intermediate insulation film.

Referring to FIGS. 8B and 8C, a second support substrate 220 may be adhered on the transistor layer 120 (or on the wiring layer if the wiring layer is formed on the transistor layer 120) to support one surface of the transistor layer 120. After turning the multi-layer structure, which includes the first support substrate 210 and the second support substrate 220, upside down, the first support substrate 210 may be removed. In other words, after placing the first support substrate 210 above the second support substrate 220, the first support substrate 210 may be removed. For example, the first support substrate 210 may be ground to a thickness of tens of pm by a grinder, or a remaining portion thereof may be removed by an etching process. After the first support substrate 210 is removed, the trench 115 may be formed from the second surface 112 of the semiconductor layer 110, which is exposed to the outside, toward a region between portions where the photo detecting device PD and the charge storage device SD form part of the first surface 111 of the semiconductor layer 110.

The trench 115 may be formed by trench isolation, such as DTI. After the trench 115 is formed in the semiconductor layer 110 to an appropriate depth by the trench isolation, the trench 115 may be filled with a material having a lower refractive index than that of a material of the semiconductor layer 110. As illustrated in FIGS. 1A and 4, the trench 115 totally reflects the light incident on the semiconductor layer 110 and directed toward the charge storage device SD from the contact surface between the semiconductor layer 110 and the trench 115, such that the light is not absorbed by the charge storage device SD.

Referring to FIG. 8D, a material layer 130 may be formed on the second surface 112 of the semiconductor layer 110. The material layer 130 may be an insulation layer, and may be a passivation layer for protecting the semiconductor layer 110. According to the exemplary embodiment, a shield 135 may be formed within the semiconductor layer 130. As described above with reference to FIG. 4, the shield 135 may prevent light from being absorbed by the charge storage device SD by blocking a part of light incident on the semiconductor layer 110. The shield 135 may include a material that does not transmit light, e.g., a metal.

Referring to FIG. 8E, a color filter layer 140 may be formed on the material layer 130. A lens layer 150 may be formed on the color filter layer 140. The lens layer 150 may focus incident light on the photo detecting device PD of the unit pixel. The color filter layer 140 may transmit light of a necessary wavelength among incident light through the lens layer 150. After the color filter layer 140 is formed, a planarization layer may be formed before the lens layer 150 is formed. The planarization layer may be formed of a polyamide-based or acryl-based material having a good light transmission. After the lens layer 150 is formed, a material remaining on the surface of the lens layer 150 may be removed. A bake process may be performed to maintain the shape of the lens layer 150.

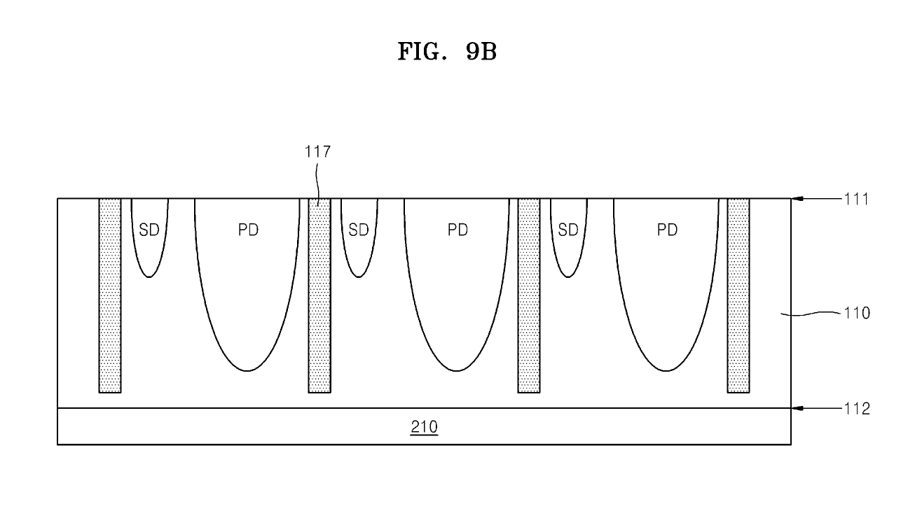

FIGS. 9A and 9B are schematic diagrams illustrating some operations of a method of manufacturing an image sensor including the unit pixel 100 of FIG. 4, according to an exemplary embodiment. According to the exemplary embodiment, a unit pixel may include a pixel isolation barrier 117.

Referring to FIG. 9A, a semiconductor layer 110 may be formed on a first support substrate 210. A surface where the first support substrate 210 and the semiconductor layer 110 contact each other is referred to as a second surface 112 of the semiconductor layer 110, and a surface of the semiconductor layer 110 which is opposite to the second surface 112 is referred to as a first surface 111 of the semiconductor layer 110. The pixel isolation barrier 117 may be formed before a photo detecting device PD and a charge storage device SD are formed within the semiconductor layer 110. The pixel isolation barrier 117 may be a DTI formed from the first surface 111 toward the second surface 112 of the semiconductor layer 110. Although the pixel isolation barrier 117 of FIG. 9A is illustrated as having a depth which is less than a thickness of the semiconductor layer 110, the pixel isolation barrier 117 may also be formed to have a depth which is equal to a thickness of the semiconductor layer 110.

Since the pixel isolation barrier 117 isolates light directed toward the photo detecting devices PD, crosstalk between adjacent pixels within the semiconductor layer 110 may be reduced. As illustrated in FIG. 5B, the pixel isolation barrier 117 included in the backside illuminated image sensor according to the exemplary embodiment may optically or electrically isolate a single photo detecting device PD and may be formed to have a grating structure.

Referring to FIG. 9B, after the pixel isolation barrier 117 is formed, the photo detecting device PD and the charge storage device SD may be formed by implanting impurities into the second surface 112 of the semiconductor layer 110. After the photo detecting device PD and the charge storage device SD are formed within the semiconductor layer 110, the operations described above with reference to FIGS. 8B to 8E may be performed.

Although the operations of forming the pixel isolation barrier 117 from the first surface 111 toward the second surface 112 of the semiconductor layer 110 are illustrated in FIGS. 9A and 9B, the pixel isolation barrier 117 may be formed from the second surface 112 toward the first surface 111 of the semiconductor layer 110. For example, the pixel isolation barrier 117 may be formed from the second surface 112 toward the first surface 111 of the semiconductor layer 110, simultaneously with or separately from forming the trench 115 illustrated in FIG. 8C.

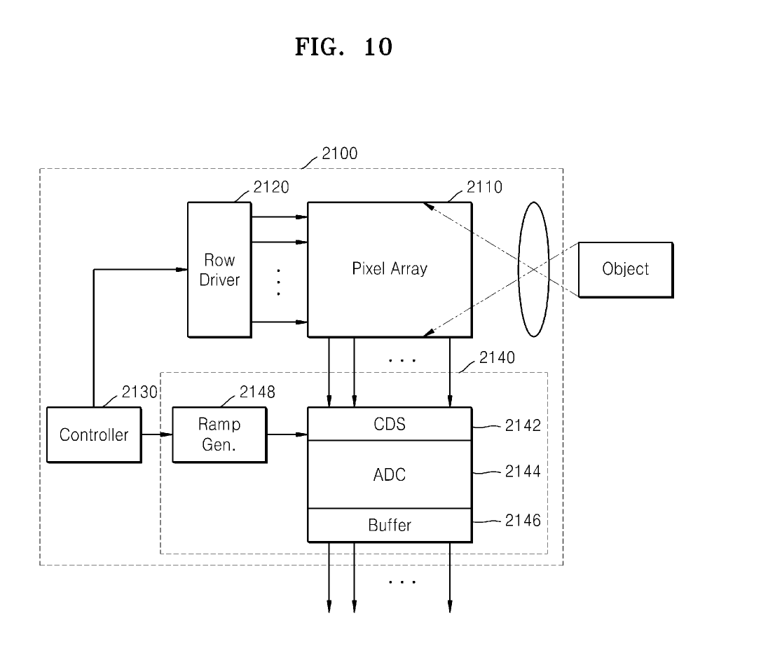

FIG. 10 is a block diagram illustrating a configuration of an image sensor 2100 according to an exemplary embodiment. As illustrated in FIG. 10, the image sensor 2100 may include a pixel array 2110, a controller 2130, a row driver 2120, and a pixel signal processing unit 2140. The pixel array 2110 may include the above-described unit pixel according to the exemplary embodiments. In other words, the charge storage device included in the unit pixel may temporarily store charges accumulated in the photo detecting device and transfer the stored charges to the floating diffusion, without influence of light absorbed from the outside.

The pixel array 2110 may include a plurality of unit pixels arranged two-dimensionally, and each of the unit pixels may include the photo detecting device. The photo detecting device may absorb light to generate charges, and an electric signal (output voltage) according to the generated charges may be provided to the pixel signal processing unit 2140 through a vertical signal line. The unit pixels included in the pixel array 2110 may provide one output voltage at a time on a row basis. Therefore, the unit pixels of a single row of the pixel array 2110 may be enabled simultaneously in response to a select signal output from the row driver 2120. The unit pixels of a selected row may provide the output voltage based on the absorbed light to an output line of a corresponding column.

The controller 2130 may control the row driver 2120 such that the pixel array 2110 absorbs light to accumulate charges, or temporarily stores the accumulated charges, and outputs an electric signal based on the stored charges to the outside of the pixel array 2110. In addition, the controller 2130 may control the pixel signal processing unit 2140 such that the output voltage provided from the pixel array 2110 is measured.

The pixel signal processing unit 2140 may include a correlated double sampler (CDS) 2142, an analog-to-digital converter (ADC) 2144, and a buffer 2146. The CDS 2142 may sample and hold the output voltage provided from the pixel array 2110. The CDS 2142 may doubly sample a specific noise level and a level of a generated output voltage, and output a level corresponding to a difference between the two levels. In addition, the CDS 2142 may receive a ramp signal generated by a ramp signal generator 2148, compare the ramp signal with the output voltage, and output a comparison result.

The ADC 2144 may convert analog signals corresponding to the levels received from the CDS 2142 into digital signals. The buffer 2146 may latch the digital signals, and the latched signals may be sequentially output to the outside of the image sensor 2100 and be transferred to an image processor (not illustrated).

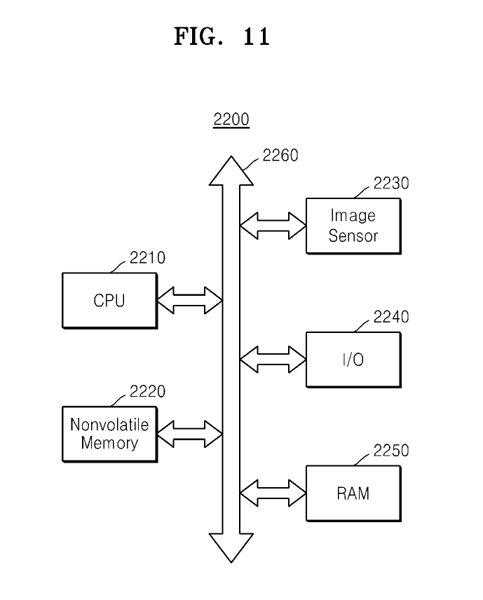

FIG. 11 is a block diagram of a system 2200 including the image sensor 2100 of FIG. 10 as an image sensor 2230, according to an exemplary embodiment. The system 2200 may be one of a computing system, a camera system, a scanner, a vehicle navigation system, a video phone, a security system, or a motion detection system, which requires image data.

As illustrated in FIG. 11, the system 2200 may include a central processing unit (CPU) (or processor) 2210, a nonvolatile memory 2220, an image sensor 2230, an input/output device 2240, and a RAM 2250. The CPU 2210 may communicate with the nonvolatile memory 2220, the image sensor 2230, the input/output device 2240, and the RAM 2250 through a bus 2260. The image sensor 2230 may be implemented with an independent semiconductor chip, or may be implemented with a single semiconductor chip by integration with the CPU 2210. The image sensor 2230 included in the system 2200 of FIG. 11 may include the above-described unit pixel according to the exemplary embodiments. In other words, the charge storage device included in the unit pixel may temporarily store charges accumulated in the photo detecting device and transfer the stored charges to the floating diffusion, without influence of light absorbed from the outside.

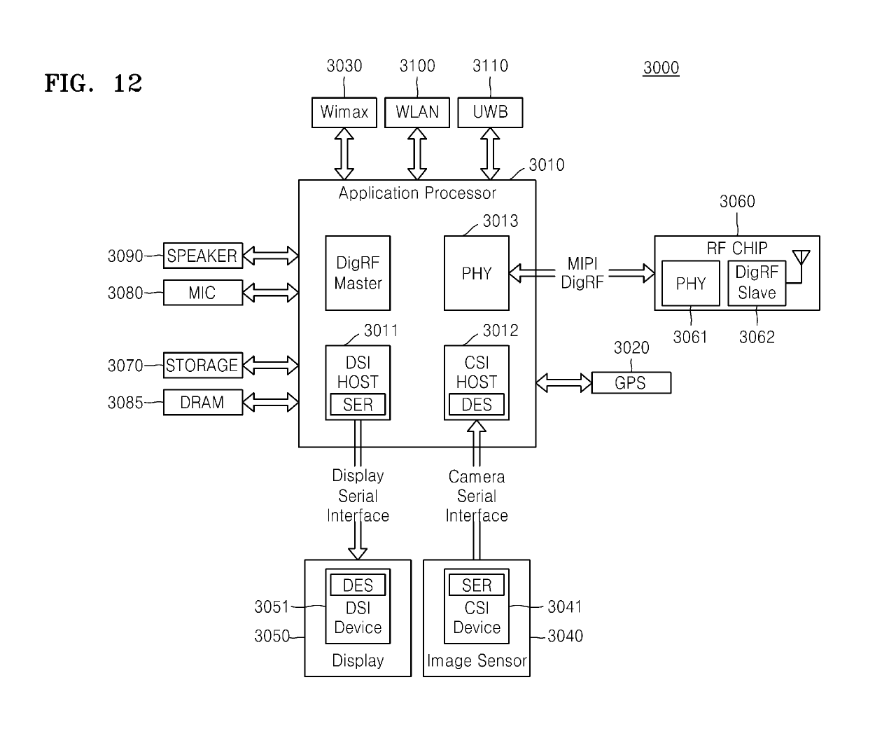

FIG. 12 illustrates an electronic system 3000 including an image sensor and an interface, according to an exemplary embodiment. Referring to FIG. 12, the electronic system 3000 may be implemented with a data processor capable of using or supporting an MIPI interface, e.g., a mobile phone, a PDA, a PMP, or a smartphone. The electronic system 3000 may include an application processor 3010, an image sensor 3040, and a display 3050.

A camera serial interface (CSI) host 3012 implemented in the application processor 3010 may perform serial communication with a CSI device 3041 of the image sensor 3040 through CSI. In this case, e.g., a photo deserializer may be implemented in the CSI host 3012, and a photo serializer may be implemented in the CSI device 3041.

A display serial interface (DSI) host 3011 implemented in the application processor 3010 may perform serial communication with a DSI device 3051 of the display 3050 through DSI. In this case, e.g., a photo serializer may be implemented in the DSI host 3011, and a photo deserializer may be implemented in the DSI device 3051.

The electronic system 3000 may further include an RF chip 3060 capable of communicating with the application processor 3010. A PHY 3013 of the application processor 3010 and a PHY 3061 of the RF chip 3060 may exchange data with each other according to MIPI DigRF.

The electronic system 3000 may further include a GPS 3020, a storage 3070, a microphone 3080, a DRAM 3085, and a speaker 3090. The electronic system 3000 may perform communication using a Wimax 3030, a WLAN 3100, and a UWB 3110.

While the exemplary embodiments have been particularly shown and described, it will be understood that various changes in form and details may be made therein without departing from the spirit and scope of the following claims.

What is claimed is:

1. An image sensor comprising:
a semiconductor layer which comprises a first surface and a second surface which is opposite to the first surface;
a photo detecting device which forms part of the first surface of the semiconductor layer and is disposed within the semiconductor layer to accumulate charges according to light absorbed from the second surface of the semiconductor layer;
a charge storage device which forms part of the first surface of the semiconductor layer and is disposed within the semiconductor layer to temporarily store the accumulated charges by the photo detecting device;
a first transfer transistor which transfers the accumulated charges by the photo detecting device to the charge storage device, the first transfer transistor comprises a gate disposed on the first surface of the semiconductor layer; and
a trench disposed from the second surface of the semiconductor layer toward a region between portions where the photo detecting device and the charge storage device form part of the first surface of the semiconductor layer.

2. The image sensor of claim 1, further comprising:
a material layer disposed on the second surface of the semiconductor layer; and
a shield disposed within the material layer to block light from being absorbed by the charge storage device through the second surface of the semiconductor layer.

3. The image sensor of claim 2, wherein the shield comprises a metal.

4. The image sensor of claim 1, wherein the trench is filled with a material having a lower refractive index than a refractive index of a material forming the semiconductor layer.

5. The image sensor of claim 4, wherein the semiconductor layer is formed of epitaxially grown silicon, and the trench is filled with an oxide, a nitride, or air.

6. The image sensor of claim 1, wherein the trench is disposed from the second surface of the semiconductor layer toward a region surrounding a portion where the charge storage device forms part of the first surface of the semiconductor layer.

7. The image sensor of claim 1, further comprising:
a floating diffusion in which the stored charges in the charge storage device are transferred; and
a second transfer transistor which transfers the stored charges in the charge storage device to the floating diffusion, the second transfer transistor comprises a gate disposed on the first surface of the semiconductor layer,
wherein the trench is disposed from the second surface of the semiconductor layer toward the first surface of the semiconductor layer, and disposed between a region where the photo detecting device and the floating diffusion form part of the first surface of the semiconductor layer.

8. The image sensor of claim 1, further comprising:
at least one unit pixel which comprises the photo detecting device and the charge storage device; and
a pixel isolation barrier disposed between adjacent unit pixels of the at least one unit pixel.

9. The image sensor of claim 1, wherein the pixel isolation barrier is filled with a material having a lower refractive index than a refractive index of a material forming the semiconductor layer.

10. A method of manufacturing an image sensor, the method comprising:
forming a photo detecting device and a charge storage device, either simultaneously or separately, by implanting impurities into a first surface of a semiconductor layer;
forming a gate of a transfer transistor on the first surface of the semiconductor layer, the transfer transistor transferring charges between the photo detecting device and the charge storage device; and
forming a trench from a second surface of the semiconductor layer, which is opposite to the first surface, to a region where the photo detecting device and the charge storage device form part of the first surface of the semiconductor layer.

11. The method of claim 10, further comprising:
forming a material layer on the second surface of the semiconductor layer; and
forming a shield within the material layer, the shield blocking light from being absorbed by the charge storage device through the second surface of the semiconductor layer.

12. The method of claim 11, further comprising:
forming a color filter layer on a surface of the material layer which is opposite to a surface contacting the second surface of the semiconductor layer; and
forming a lens layer on one surface of the color filter layer which is opposite to the surface contacting the material layer.

13. The method of claim 10, wherein the trench is filled with a material having a lower refractive index than a refractive index of a material forming the semiconductor layer.

14. The method of claim 10, wherein the trench is disposed from the second surface of the semiconductor layer toward a region surrounding a portion where the charge storage device forms part of the first surface of the semiconductor layer.

15. The method of claim 10, further comprising forming a pixel isolation barrier between adjacent unit pixels of at least one unit pixel which comprises the photo detecting device and the charge storage device.

16. A unit pixel of an image sensor, comprising:
a semiconductor layer comprising a first surface and a second surface opposite to the first surface;
a transistor layer disposed on the first surface of the semiconductor layer;
a color filter layer stacked on the second surface of the semiconductor layer;
a lens layer stacked on the color filter layer;
a photo detecting device which forms part of the first surface of the semiconductor layer; and
a charge storing device which forms part of the first surface of the semiconductor layer,
wherein the lens layer focuses incident light on a photo detecting device, and
wherein the color filter layer transmits incident light through the lens layer so that only light of a specific wavelength is incident on the photo detecting device.

17. The unit pixel of claim 16, wherein the semiconductor layer further comprises:
a trench which is formed from the second surface of the semiconductor layer.

18. The unit pixel of claim 17, wherein the trench is formed from the second surface of the semiconductor layer toward a region surrounding a portion where the charge storing device forms part of the first surface of the semiconductor layer.

19. The unit pixel of claim 16, wherein the photo detecting device accumulates charges according to light absorbed from the second surface of the semiconductor layer, and
wherein the charge storing device temporarily stores the accumulated charges by the photo detecting device.
